(19) United States
(12) Patent Application Publication
(10) Pub. No.: US 2009/0315133 A1
(43) Pub. Date: Dec. 24, 2009

(54) IMAGE SENSOR MODULE AND CAMERA MODULE HAVING SAME

(75) Inventor: JEN-TSORNG CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/344,661

(22) Filed: Dec. 29, 2008

(30) Foreign Application Priority Data
Jun. 19, 2008 (CN) 200810302229.5

(51) Int. Cl. H01L 27/00

(52) U.S. Cl. 257/433; 257/E27.001

(57) ABSTRACT

An exemplary image sensor module includes a heat pipe and an image sensor. The heat pipe includes a main body and a working fluid. The main body includes a top flat cover, an opposite bottom flat cover and a chamber cooperatively defined between the top cover and the bottom cover. The working fluid is filled in the chamber. The image sensor is in thermal contact with an evaporation end of the heat pipe.

### BACKGROUND

1. Technical Field

The present invention relates to an image sensor module and a camera module using the image sensor module.

2. Discussion of Related Art

Currently, with the development of electronic devices having multiple functions, image pick-up apparatuses have been widely used in a variety of consumer electronic devices, such as cellular telephones, notebook computers, digital cameras, personal digital assistants (PDAs), etc. In the meantime, demand for improving image quality is increasing, which essentially depends on the quality of a camera module of the image pick-up apparatus. Accordingly, a camera module with high resolution and image quality is desired.

A key component of a camera module is an image sensor module. With the development of camera modules, the resolution of image sensor modules is greatly increased. Accordingly, image sensor modules deal with a great deal of image data, and at the same time generate a significant amount of heat. The overheating of the image sensor module may influence the stability of the image sensor modules and the camera modules.

Therefore, what is needed is an image sensor module having high heat dissipation efficiency.

### BRIEF DESCRIPTION OF THE DRAWINGS

Many aspects of the present image sensor module can be better understood with reference to the following drawings. The components in the drawings are not necessarily to scale, the emphasis instead being placed upon clearly illustrating the principles of the present image sensor module. Moreover, in the drawings, like reference numerals designate corresponding parts throughout the several views.

FIG. 1 is a schematic, cross-sectional view of a camera module in accordance with an exemplary embodiment.

FIG. 2 is a schematic, cross-sectional view of an image sensor module of the camera module of FIG. 1.

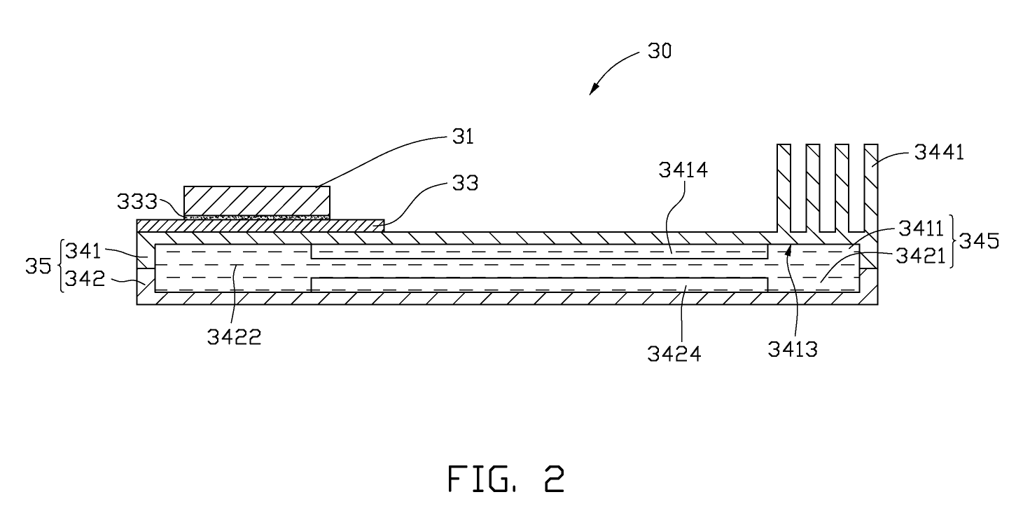

FIG. 3 is a schematic, exploded view of the image sensor module of the camera module of FIG. 1.

FIG. 4 is a schematic, isometric view of top cover of the main body of the heat pipe in the camera module of FIG. 3.

### DETAILED DESCRIPTION OF EMBODIMENTS

Reference will now be made to the drawings to describe in detail of the exemplary embodiments of the image sensor module.

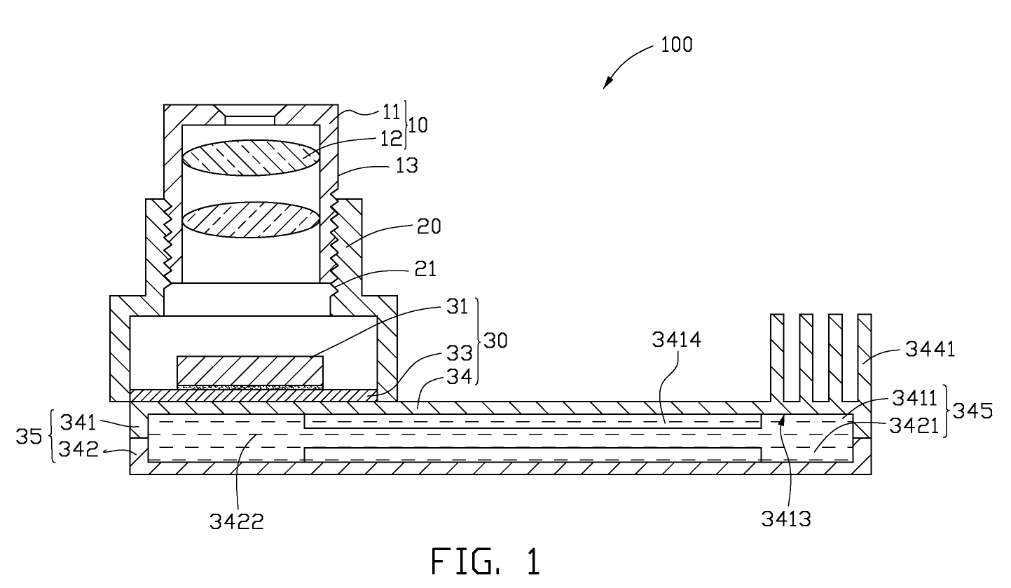

Referring to FIGS. 1, a camera module 100, in accordance with an exemplary embodiment, includes a lens module 10, a holder 20, and an image sensor module 30.

The lens module 10 includes a barrel 11 and a plurality of lenses 12 received in the barrel 11. The barrel 11 is a hollow cylinder, including an inner wall and an outer wall 13. The outer wall 13 has screw threads for mounting the lens module 10 to the holder 20.

The holder 20 is a hollow cylinder with a round top and a rectangular bottom. The round top is disposed for coupling with the barrel 11, and partly receiving the barrel 11. The top inner wall 21 of the holder 20 has screw threads, matching with the screw threads on the outer wall 13 of the barrel 11, for mounting the barrel 11 to the holder 12. The quadrate bottom of the holder 20 includes a housing space for partly receiving the image sensor module 30.

The image sensor module 30 includes an image sensor 31, a heat metallic conducting board 33 and a heat pipe 34. The heat pipe 34 is a flat/planar heat pipe.

The image sensor 31 is configure for sensing the image and transferring light signals to electric signals. The image sensor 31 may be a charge coupled device (CCD) or a complementary metal oxide semiconductor (CMOS). In the present embodiment, the image sensor 31 is a CCD sensor.

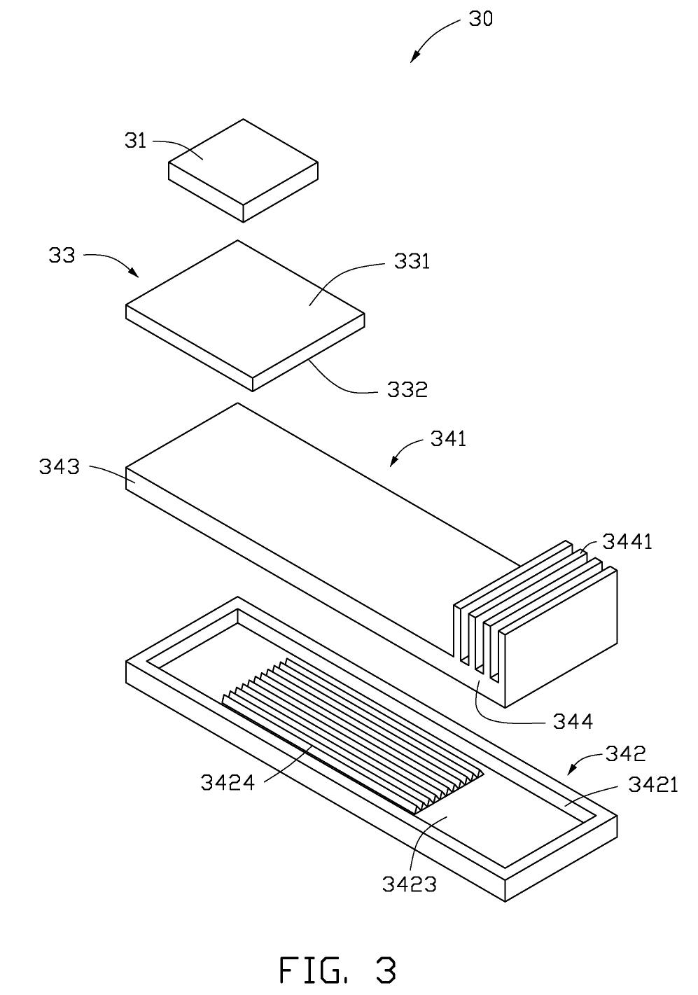

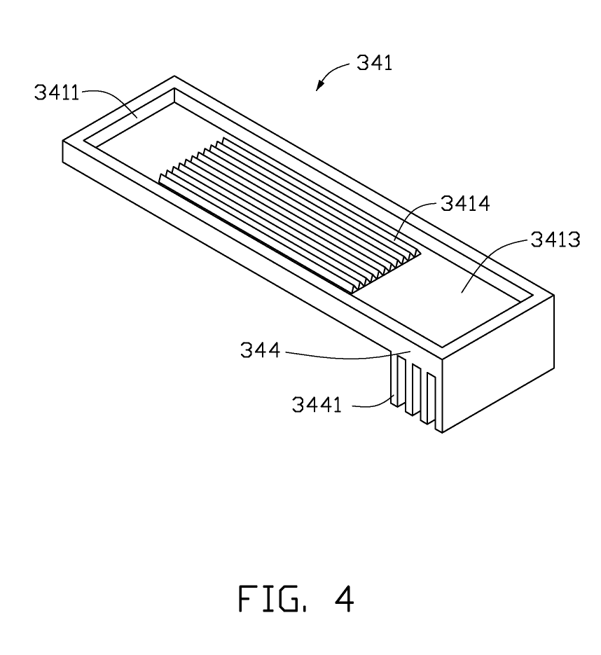

Referring to FIGS. 3 and 4, the heat conducting board 33 includes a first surface 331 and an opposite second surface 332. The heat conducting board 33 is made of highly thermal conductive materials. In the present embodiment, the heat conducting board 33 is made of copper. To enhance the thermal conductive efficiency, the first surface 331 includes a thermal interface material (TIM) layer 333 to quickly conduct the heat of the sensor 31 to the heat conducting board 33. Correspondingly, the second surface 332 may also have a TIM layer. The heat conducting board 33 may be flexible circuit board or printed circuit board. The heat conducting board 33 includes lead lines (not shown) which is electrically connected with the image sensor 31.

The heat pipe 34 includes a main body 35 and a working fluid 3422. The heat pipe 34 has an evaporation end 343 and a condensation end 344. The heat conducting board 33 is in thermal contact with the evaporation end 343 of the heat pipe 34.

The main body 35 includes a top flat cover 341 and an opposite bottom flat cover 342 cooperatively defining a chamber 345 therebetween. The bottom cover 342 defines a cavity 3421. Accordingly, the top cover 341 also defines a cavity 3411. The two cavities 3411, 3421 cooperatively forms the chamber 345. It should be understood that the cavities 3411, 3422 could be arranged only on the top cover 341 or the bottom cover 342. The shape of the cavity 3411 is rectangular in cross-section. The chamber 345 is filled with the working fluid 3422. The top cover 341 and the bottom cover 342 are bonded by a wafer bonding process.

In the present embodiment, the top cover 341 and the bottom cover 342 are rectangular with the same shape. The scope of the length of the rectangle is from 10 mm to 50 mm. The scope of the width of the rectangle is from 5 mm to 50 mm. The scope of the thickness of the top cover 341 and the bottom cover 342 is from 100 μm to 1000 μm. It should be understood that the top and the bottom covers 341, 342 may be other shapes, such as rhombic or trapezoid.

The bottom cover 342 includes an inner surface 3423 and a plurality of juxtaposed strip-shaped protrusions 3424 formed on the inner surface 3423. The protrusions 3424 cooperatively form a plurality of V-shaped grooves. Accordingly, the inner surface 3413 of the top cover 341 also defines a plurality of protrusions 3414. The protrusions 3414 are juxtaposed and cooperatively form a plurality of V-shaped grooves too. The protrusions 3414, 3424 form wick structures and are helpful to make the cold working fluid 3422 to return back to the evaporation end 343 of the heat pipe 34. The plurality of V-shaped grooves also can be U-shaped.

In the present embodiment, the top cover 341 and the bottom cover 342 are made of silicon. The cavity 3421 and the protrusions 3414, 3424 may be produced by a silicon etching process. It should be understood that the top and the bottom covers 341, 342 may be made of other materials that is known as a heat pipe material.

To enhance the thermal dissipation efficiency, the image sensor module 30 further includes a plurality of fins 3441 in thermal contact with the condensation end 344 of the heat pipe 34. Alternatively, a fan (not shown) may be attached to the condensation end 344 to quickly cooling down the working fluid 3422 on the condensation end 344.

The present embodiment of the image sensor module and the camera module having the image sensor module includes following advantages: the image sensor module includes a heat pipe to efficiently cooling down the temperature of the image sensor, so to increase the stability of image sensor modules and camera modules.

While the present invention has been described as having preferred or exemplary embodiments, the embodiments can be further modified within the spirit and scope of this disclosure. This application is therefore intended to cover any variations, uses, or adaptations of the embodiments using the general principles of the invention as claimed. Further, this application is intended to cover such departures from the present disclosure as come within known or customary practice in the art to which the invention pertains and which fall within the limits of the appended claims or equivalents thereof.

What is claimed is:

1. An image sensor module comprising:
a heat pipe comprising
a main body comprising a top flat cover, an opposite bottom flat cover and a chamber cooperatively defined between the top cover and the bottom cover; and
a working fluid filled in the chamber; and
an image sensor in thermal contact with an evaporation end of the heat pipe.

2. The image sensor module of claim 1, wherein the top cover comprises an inner surface and a plurality of juxtaposed strip-shaped protrusions formed on the inner surface.

3. The image sensor module of claim 1, wherein the bottom cover comprises an inner surface and a plurality of juxtaposed strip-shaped protrusions formed on the inner surface.

4. The image sensor module of claim 2, wherein the protrusions cooperatively form a plurality of V-shaped grooves or U-shaped grooves.

5. The image sensor module of claim 1, further comprising a metallic heat conducting board arranged between the image sensor and the heat pipe, wherein the heat conducting board is in thermal contact with the image sensor and the evaporation end of the heat pipe.

6. The image sensor module of claim 5, further comprising a thermal interface material layer, wherein the heat conducting board is thermally coupled to the image sensor via the thermal interface material layer.

7. The image sensor module of claim 1, wherein the top cover and the bottom cover are made of silicon.

8. The image sensor module of claim 1, wherein the top cover and the bottom cover are substantially rectangular.

9. The image sensor module of claim 1, further comprising a plurality of fins in thermal contact with a condensation end of the heat pipe.

10. A camera module comprising:
a lens module;
a holder; and
an image sensor module, the holder receiving the lens module and the mage sensor module therein, the image sensor module comprising:
a heat pipe comprising
a main body comprising a top flat cover and an opposite bottom flat cover and a chamber cooperatively defined between the top cover and the bottom cover; and
a working fluid filled in the chamber; and
an image sensor in thermal contact with an evaporation end of the heat pipe.

11. The camera module of claim 10, wherein the top cover comprises an inner surface and a plurality of juxtaposed strip-shaped protrusions formed on the inner surface.

12. The camera module of claim 10, wherein the bottom cover comprises an inner surface and a plurality of juxtaposed strip-shaped protrusions formed on the inner surface.

13. The camera module of claim 10, wherein the protrusions cooperatively form a plurality of V-shaped grooves or U-shaped grooves.

14. The camera module of claim 10, further comprising a metallic heat conducting board arranged between the image sensor and the heat pipe, wherein the heat conducting board is in thermal contact with the image sensor and the evaporation end of the heat pipe.

15. The camera module of claim 14, further comprising a thermal interface material, wherein the heat conducting board is thermally coupled to the image sensor via the thermal interface material layer.

16. The camera module of claim 10, wherein the top cover and the bottom cover are made of silicon.

17. The camera module of claim 10, wherein the top cover and the bottom cover are substantially rectangular.

18. The camera module of claim 10, further comprising a plurality of fins in thermal contact with a condensation end of the heat pipe.
